(19) United States
(12) Patent Application Publication
(10) Pub. No.: US 2024/0096516 A1
(43) Pub. Date: Mar. 21, 2024

(54) BONDING WIRE FOR SEMICONDUCTOR PACKAGE

(71) Applicants: Woong Chul SHIN, Daejeon (KR); Min BAEK, Daejeon (KR)

(72) Inventors: Woong Chul SHIN, Daejeon (KR); Min BAEK, Daejeon (KR)

(21) Appl. No.: 18/273,497

(22) PCT Filed: Jan. 21, 2022
(86) PCT No.: PCT/KR2022/001108

§ 371 Date: Jul. 20, 2023

(30) Foreign Application Priority Data
Jan. 22, 2021 (KR) 10-2021-0009620
Mar. 19, 2021 (KR) 10-2021-0035587

(51) Int. Cl. H01B 1/02; H01B 3/10

(52) U.S. Cl. CPC H01B 1/02; H01B 3/10; H01L 23/49811

(57) ABSTRACT

Provided is a bonding wire for a semiconductor package, which includes an insulating layer formed on the outer surface of a core portion by a thin layer deposition method, so that the occurrence of a short-circuit during wire bonding is fundamentally prevented and bondability is improved. The bonding wire for a semiconductor package comprises: a core portion formed of a conductive metal; and an insulating layer formed on the outer surface of the core portion by a thin layer deposition method.

### TECHNICAL FIELD

The present invention relates to a bonding wire for a semiconductor package, and more particularly, to a boning wire for a semiconductor package, which includes an insulating layer formed on the outer surface of a core portion by a thin layer deposition method, so that the occurrence of a short circuit during wire bonding is fundamentally prevented and bondability is improved.

### BACKGROUND ART

A bonding wire is used in a packaging process for electrically connecting an electrode of a semiconductor device and a lead frame of a printed circuit board. In a conventional art, gold having excellent electrical conductivity, thermal conductivity, and chemical resistance has been used for the bonding wire.

However, gold has a problem in that it is a precious metal whose price is very high, resulting in an increase in the production cost of the semiconductor package. Therefore, studies have been conducted on bonding wires using low-cost main materials (silver, copper, etc.) in order to replace the existing bonding wires using gold as a raw material.

Copper (Cu) bonding wires having excellent electrical conductivity have been developed to replace the bonding wire formed of gold, but they have a problem in terms of bondability because the surface thereof is likely to be oxidized when exposed to air. In addition, they also have a problem in that a short circuit occurs due to contact between bonding wires because the distance between adjacent bonding wires becomes shorter as the degree of integration of semiconductor devices increases.

Therefore, a technique of forming palladium on the outer surface of a copper bonding wire or coating the outer surface with a polymer has been proposed. However, in the case in which palladium is formed, there is a problem in that the electrical resistance of palladium is 6 times higher than that of copper, and in the case in which the outer surface is coated with the polymer, there is a problem in that, after wire bonding, bonding properties are poor and bondability is also poor.

### DISCLOSURE

### Technical Problem

A technical problem to be achieved by the present invention is to provide a boning wire for a semiconductor package, which includes an insulating layer formed on the outer surface of a core portion by a thin layer deposition method, so that the occurrence of a short circuit during wire bonding is fundamentally prevented and bondability is improved.

### Technical Solution

A bonding wire for a semiconductor package according to the present invention for achieving the above technical problem includes: a core portion formed of a conductive metal; and an insulating layer formed on the outer surface of the core portion by a thin layer deposition method.

In the present invention, the core portion is preferably of a circular shape having a cross-sectional diameter of 1 μm to 10,000 μm.

In the present invention, the core portion is preferably formed of any one of copper, gold, silver, and aluminum, or includes palladium (Pd) alloyed to the outer surface of any one of copper, gold, silver, and aluminum.

In the present invention, the insulating layer is preferably formed to have a thickness of 1 nm to 1,000 nm by an atomic layer deposition method.

In the present invention, the insulating layer is preferably an oxide layer containing any one of aluminum, zinc, titanium, and silicon.

In the present invention, the insulating layer is preferably any one of Al₂O₃, ZnO₂, TiO₂, and SiO₂.

In the present invention, the thin layer deposition method is preferably any one selected from among an atomic layer deposition method, a chemical vapor deposition method, and a sputtering method.

### Advantageous Effects

According to the bonding wire for a semiconductor package according to the present invention, there are advantages in that the insulating layer formed on the outer surface of the core portion may prevent a short circuit from occurring due to contact between the bonding wires, and in that the insulating layer improves bondability by forming an intermetallic compound (IMC) during wire bonding.

### BRIEF DESCRIPTION OF DRAWINGS

FIG. 1 is a schematic cross-sectional view of a bonding wire for a semiconductor package according to one embodiment of the present invention.

### BEST MODE

Hereinafter, a specific embodiment of the present invention will be described in detail with reference to the accompanying drawing.

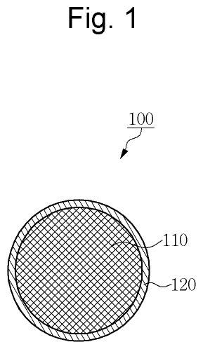

As shown in FIG. 1, a bonding wire 100 for a semiconductor package according to this embodiment includes a core portion 110 and an insulating layer 120.

First, the core portion 110 corresponds to the overall appearance shape of the bonding wire 100 for a semiconductor package according to this embodiment, and preferably has a circular cross-section. In addition, the core portion 110 is formed of a metal having excellent electrical conductivity, and has a cross-sectional diameter of about 10 μm to 50 μm. In this case, it is preferable that the cross-sectional diameter of the core portion 110 is 1 μm to 10,000 μm.

Meanwhile, in this embodiment, the core portion 110 may be formed of any one of copper (Cu), gold (Au), silver (Ag), aluminum (Al), which is a metal having excellent electrical conductivity, or may include palladium (Pd) alloyed to the outer surface of any one of copper (Cu), gold (Au), silver (Ag), and aluminum (Al). In particular, in this embodiment, the core portion 110 is preferably formed of copper or silver.

Next, as shown in FIG. 1, the insulating layer 120 is formed on the outer surface of the core portion 110 by a thin layer deposition method, and is a component having electrical insulating properties. As used herein, the term “thin layer deposition method” refers to a deposition method capable of uniformly forming a thin insulating layer having a thickness of 1 to 1,000 nm. For example, the insulating layer 120 is formed by an atomic layer deposition method, a chemical vapor deposition method, or a sputtering method, and has electrical insulating properties.

In this embodiment, the insulating layer 120 is preferably formed to have a very small thickness of 1 nm to 30 nm, more preferably 5 nm to 10 nm, by an atomic layer deposition method. Coating the entire surface of the core portion 110 with the insulating layer having a uniform small thickness may be performed by an atomic layer deposition method.

In addition, in this embodiment, the insulating layer 120 is preferably an oxide layer containing any one of aluminum (Al), zinc (Zn), titanium (Ti), and silicon (Si). Thus, the insulating layer 120 is preferably any one of Al₂O₃, ZnO₂, TiO₂, and SiO₂.

### MODE FOR INVENTION

Meanwhile, the bonding wire 100 for a semiconductor package according to this embodiment may also include: the core portion 110; the insulating layer 120; and a buffer layer (not shown in the FIGURE) between the core portion 110 and the insulating layer 120.

### INDUSTRIAL APPLICABILITY

According to the present invention, it is possible to produce a bonding wire which is not likely to cause a short circuit during packaging or use, and in particular, the bonding wire has improved bondability during a bonding operation, and thus may be used in the semiconductor industry.

1. A bonding wire for a semiconductor package comprising: a core portion formed of a conductive metal; and an insulating layer formed on an outer surface of the core portion by a thin layer deposition method.

2. The bonding wire according to claim 1, wherein the core portion is of a circular shape having a cross-sectional diameter of 1 μm to 10,000 μm.

3. The bonding wire according to claim 1, wherein the core portion is formed of any one of copper, gold, silver, and aluminum, or comprises palladium (Pd) alloyed to an outer surface of any one of copper, gold, silver, and aluminum.

4. The bonding wire according to claim 1, wherein the insulating layer is formed to have a thickness of 1 nm to 1,000 nm by an atomic layer deposition method.

5. The bonding wire according to claim 1, wherein the insulating layer is an oxide layer containing any one of aluminum, zinc, titanium, and silicon.

6. The bonding wire according to claim 1, wherein the insulating layer is any one of Al₂O₃, ZnO₂, TiO₂, and SiO₂.

7. The bonding wire according to claim 1, wherein the thin layer deposition method is any one selected from among an atomic layer deposition method, a chemical vapor deposition method, and a sputtering method.
